(19) United States
(12) Patent Application Publication
(10) Pub. No.: US 2013/0056053 A1
(43) Pub. Date: Mar. 7, 2013

(54) SOLAR CELL

(71) Applicants: Anthony Lochtefeld, Ipswich, MA (US); Andrew Gerger, Boston, MA (US)

(72) Inventors: Anthony Lochtefeld, Ipswich, MA (US); Andrew Gerger, Boston, MA (US)

(73) Assignee: AMBERWAVE INC., Salem, NH (US)

(21) Appl. No.: 13/602,679

(22) Filed: Sep. 4, 2012

Related U.S. Application Data
(60) Provisional application No. 61/530,680, filed on Sep. 2, 2011.
(60) Provisional application No. 61/650,133, filed on May 22, 2012.
(60) Provisional application No. 61/657,698, filed on Jun. 8, 2012.

(51) Int. Cl. H01L 31/0687; H01L 31/18

(52) U.S. Cl. 136/255; 438/73; 257/E31.124

(57) ABSTRACT

A device, system, and method for a multi-junction solar cell is described herein. An exemplary silicon germanium solar cell structure has a substrate with a graded buffer layer grown on the substrate. A base layer and emitter layer for a first solar cell are grown in or on the graded buffer layer. A first junction is provided between the emitter layer and the base layer. A second solar cell is grown on top of the first solar cell.

### RELATED APPLICATIONS

This application claims the benefit of and priority to U.S. Provisional Application Ser. No. 61/530,680 filed Sep. 2, 2011, U.S. Provisional Application Ser. No. 61/650,133 filed May 22, 2012, and U.S. Provisional Application Ser. No. 61/657,698 filed Jun. 8, 2012, the disclosures of which are hereby incorporated by reference in their entirety.

### STATEMENT REGARDING FEDERALLY SPONSORED RESEARCH OR DEVELOPMENT

Portions of the present invention may have been made in conjunction with Government funding under contract number HR0011-07-9-0005, and there may be certain rights to the Government.

### TECHNICAL FIELD

The present invention relates to solar cells and more particularly, relates to a solar cell utilizing a graded buffer.

### BACKGROUND

There is considerable interest in the design and fabrication of tandem multi-junction solar cells for high efficiency photovoltaics for space-based and terrestrial applications. Multi-junction solar cells comprise two or more p-n junction subcells with band gaps engineered to enable efficient collection of the broad solar spectrum. The subcell band gaps are controlled such that as the incident solar spectrum passes down through the multi-junction solar cell it passes through subcells of sequentially decreasing band gap energy. Thus, the efficiency losses associated with single junction cells—inefficient collection of high-energy photons and failure to collect low-energy photons—are minimized.

### SUMMARY

The present invention is a device, system, and method for multi-junction solar cell structure utilizing a graded buffer. An exemplary silicon germanium solar cell structure can have a substrate with a graded buffer layer grown on the substrate. A base layer and emitter layer for a first solar subcell is grown in or on the graded buffer layer. A first junction can be provided between the emitter layer and the base layer. A second solar subcell can be grown on top of the first solar subcell.

The present invention is not intended to be limited to a system or method that must satisfy one or more of any stated objects or features of the invention. It is also important to note that the present invention is not limited to the exemplary or primary embodiments described herein. Modifications and substitutions by one of ordinary skill in the art are considered to be within the scope of the present invention, which is not to be limited except by the following claims.

### BRIEF DESCRIPTION OF THE DRAWINGS

These and other features and advantages of the present invention will be better understood by reading the following detailed description, taken together with the drawings wherein:

FIG. 1 is a profile diagram of a completed device in accordance with the exemplary multi-junction cell embodiment of the invention.

FIGS. 2(a-d) are profile diagrams of a device being constructed in accordance with an exemplary multi-junction cell embodiment of the invention.

FIG. 3 is a flow chart of exemplary actions used to construct a device in accordance with the exemplary multi-junction cell embodiment of the invention.

FIG. 4 is a profile diagram of a completed device in accordance with the exemplary multi-junction cell on a transparent substrate embodiment of the invention.

FIGS. 5(a-h) are profile diagrams of a device being constructed in accordance with an exemplary multi-junction cell on a transparent substrate embodiment of the invention.

FIG. 6 is a flow chart of exemplary actions used to construct a device in accordance with the exemplary multi-junction cell on a transparent substrate embodiment of the invention.

### DETAILED DESCRIPTION OF THE PREFERRED EMBODIMENTS

### General

Solar modules using 16% efficient solar cells dominate the present photovoltaic market, but even at today's very low price per watt, they cannot be profitably installed without significant subsidies, in most parts of the world. This is in part because the non-module cost or balance of systems (BOS) cost dominates total installation cost. Most of these BOS costs are area dependent and scale linearly with area. Therefore, higher efficiency solar cells reduce BOS costs, by reducing the amount of solar installation area for a given power output. For example, for residential-based rooftop installations, a doubling of efficiency can be estimated to lead to about a 20-30% decrease in total system installation cost per watt.

According to one embodiment of the invention, a tandem cell on silicon has the potential for at least 33% cell efficiency, or about double that of today's market-dominating low-cost silicon-based solar cells. Embodiments may make use of the SiGe graded buffer to allow the growth of low-dislocation density SiGe with Ge content of, for example, about 80% on a silicon wafer. The top subcell can be GaAsP lattice matched to the SiGe below it. The GaAsP can have a bandgap of about 1.6 eV. The bottom subcell can be SiGe, above the SiGe graded buffer. The SiGe of the bottom subcell can have a bandgap of about 0.9 eV.

Embodiments offer additional benefits for high efficiency multi-junction solar cells based on III-V epitaxial subcells grown on silicon germanium subcells grown on graded buffers of silicon germanium on silicon substrates. Currently, the monocrystalline germanium substrate used for almost all commercial multi-junction III-V solar cells accounts for the majority of the cost of such solar cells, even though only the top portion of this substrate contributes to solar cell operation.

### Solar Cell

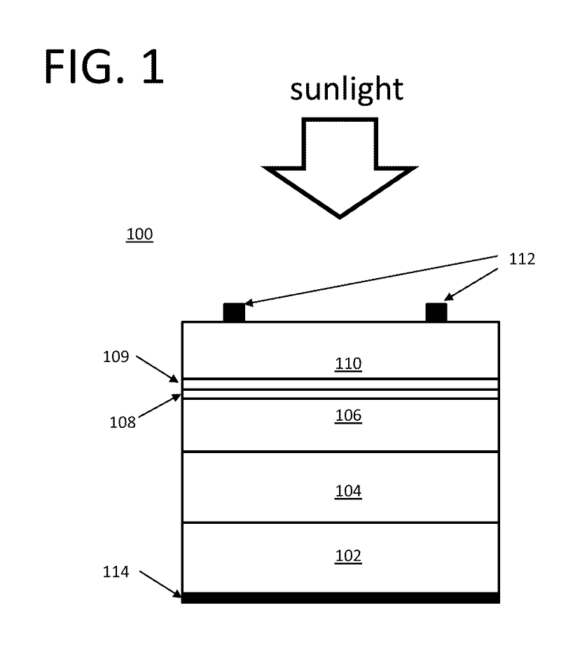

Referring to FIG. 1, the multi-junction cell 100 may have the exemplary basic structure. A monocrystalline silicon substrate 102 may be used to construct a first portion of a solar cell 100. A graded buffer layer 104 can be hetero-epitaxially grown on the substrate 102. A SiGe subcell 106 can be grown on the graded buffer layer 104. A GaAsP subcell 110 can be grown on the SiGe subcell 106. A tunnel junction 108 can be provided between the GaAsP subcell 110 and the SiGe subcell 106. Transition layers 109 can be provided between the tunnel junction 109 and the GaAsP subcell 110. Top contacts 112 can be provided on the exposed surface of the GaAsP subcell 110. Bottom contact and/or reflective surface 114 can be provided on the bottom surface of the substrate. Although exemplary embodiments describe a SiGe subcell, embodiments are not limited to SiGe and can include a solar subcell constructed of other materials suitable for providing a graded buffer. Additionally, embodiments are not limited to a top GaAsP subcell and can include a solar subcell constructed of other material suitable for growth over the bottom subcell.

### Exemplary Solar Cell Production

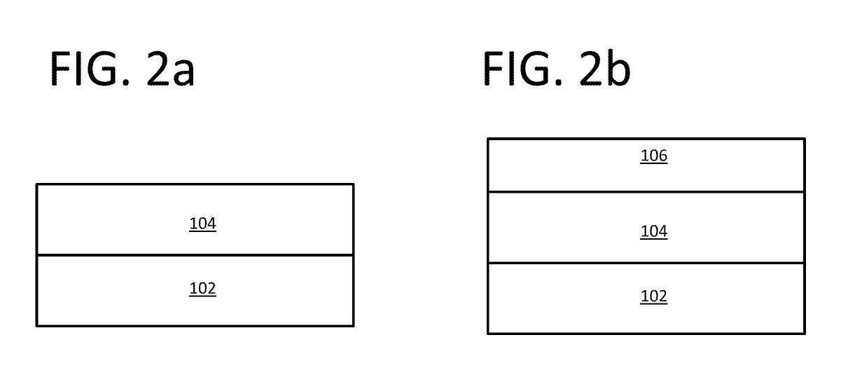

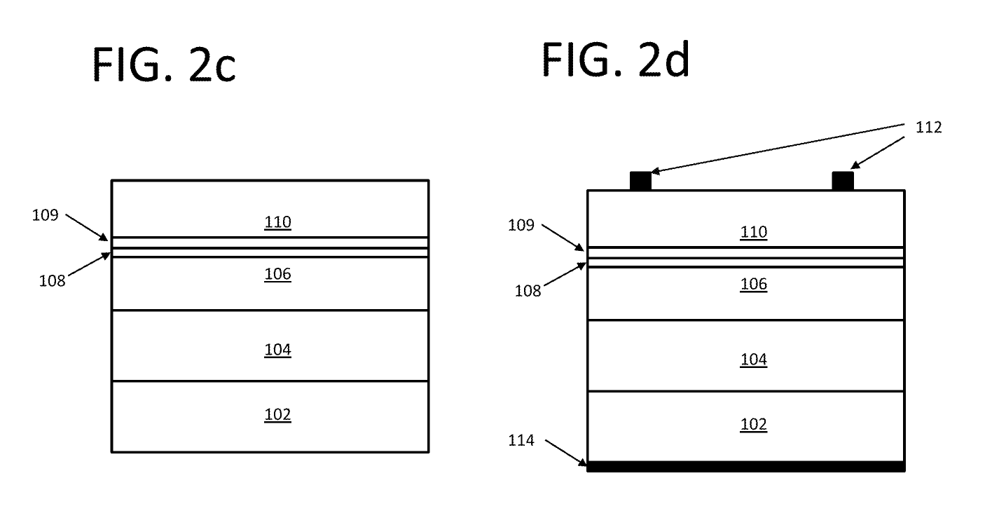

Referring to FIGS. 2(a-d), an exemplary solar cell device is constructed in accordance with an exemplary multi-junction embodiment of the invention. The starting substrate 102 may be monocrystalline silicon with n-type doping, for example arsenic or phosphorous, for example in the range 1×10¹⁶ cm⁻³ to 1×10¹⁹ cm⁻³. Substrate 102 may be, for example, but not limited to, a (100) surface orientation with an offcut of 2-8 degree towards a <110> or <111> direction; for example, the surface offcut may be 4-6 degrees toward a <110> or <111> direction. The substrate 102 may have a thickness of about 100-1000 microns; for example, the thickness may be between 200 and 500 microns. The substrate 102 can be metallurgical grade monocrystalline silicon. The diameter of the substrate 102 may be, but is not limited to, standard wafer sizes of about 100-300 mm. Alternately, substrate 102 may be square or semi-square with a size of e.g. 125 mm or 156 mm across, typical sizes for Si solar cells.

The graded buffer layer 104 can be hetero-epitaxially grown on the substrate 102. A CVD reactor such as an ASM Epsilon 2000 can be used to produce the relaxed graded buffer layer on substrate 102; alternately, a batch epitaxy reactor can be used. The various doping levels described in the graded buffer structure and SiGe subcell layers can be incorporated in-situ during epitaxial growth, by means well known in the art. The composition of the graded buffer layer 104 can be initiated with a 0% or relatively low germanium composition. A germanium content, x, of the Si₁₋ₓGeₓ layer is controlled by the relative concentration of the silicon and germanium precursors. By increasing the germanium content gradually, the strain due to lattice mismatch between silicon and germanium is gradually relieved, thereby minimizing threading dislocation density in the deposited relaxed SiGe layer. Typically, the germanium content of the graded Si₁₋ₓGeₓ layer is increased at a rate of about 10%-25% germanium per micron; however, embodiments need not be limited to that range. A final graded Si₁₋ₓGeₓ layer can comprise a 50-90% germanium composition, or for example 70-85% germanium composition. However, embodiments are not limited to that composition and various grading layers may be incorporated or may form a portion of the SiGe subcell 106. An exemplary process of growing the graded buffer layer 104 is described in greater detail and incorporated herein in U.S. Pat. No. 5,221,413 of Jun. 22, 1993 entitled: “Method for making low defect density semiconductor heterostructure and devices made thereby”. Graded buffer layer 104 may be doped n-type, with for example arsenic or phosphorous, for example in the range 1×10¹⁶ cm⁻³ to 1×10¹⁹ cm⁻³.

The SiGe subcell 106 can include a back surface field layer interfacing graded buffer layer 104, with Ge composition anywhere between 50-90%, approximately matched to the terminal germanium composition of graded buffer layer 104. The back surface field layer can have a thickness of e.g. 50-500 nm with n type doping levels of about 1e¹⁷-1e¹⁹ cm⁻³, or for example 3e¹⁷-3e¹⁸ cm⁻³. In an alternative embodiment, the back surface field layer may be tensile, with a germanium content lower than that of the terminal composition of graded buffer layer 104, for example about 25% lower Ge; in this case, the thickness of the back surface field layer may be thinner, for example about 20-100 nm. Due to the energy band offsets introduced by tension, a tensile back surface field layer may be more effective than a lattice-matched one. SiGe subcell 106 can include a base layer, with a Ge composition anywhere between 50-90%, approximately matched to the terminal germanium composition of graded buffer layer 104. The base layer can have a thickness of between 0.5-5.0 um with n type doping levels of about 1e¹⁵-5e¹⁷ cm⁻³, or for example levels of about 5e¹⁵-5e¹⁶ cm⁻³. If the back surface field layer is included, it can be below and in contact with the base layer.

An emitter layer can be grown on top of the base layer having a similar germanium composition or matched to the surface of the base layer. The emitter layer can have a p type doping level of 5e¹⁷-5e¹⁹ cm⁻³, or for example levels of about 1e¹⁸-5e¹⁸ cm⁻³.

The emitter layer can have a thickness of about 100-2000 nm, or for example about 200-500 nm. An exemplary process of growing a SiGe solar cell is described in greater detail and incorporated herein in U.S patent application publication 2011/0120538 published May 26, 2011 entitled: “Silicon Germanium Solar Cell”.

The tunnel junction 108 can be provided between the SiGe subcell 106 and GaAsP subcell 110. The tunnel junction 108 can comprise a bottom tunnel junction portion comprised of SiGe interfacing SiGe subcell 106, with p-type doping levels of about 7e¹⁸-1e²⁰ cm⁻³ with a thickness of 5-20 nm. The percent of germanium can be approximately matched to the terminal germanium composition of graded buffer 104, or it can be richer in germanium (e.g up to about 20% higher in Ge content, and may be pure Ge) for narrower bandgap to promote more effective tunneling behavior. A top SiGe tunnel junction portion can be provided having n type doping levels of about 7e¹⁸-1e²⁰ cm⁻³ with a thickness of 5-20 nm. Again, the percent of germanium can be approximately matched to the terminal germanium composition of graded buffer 104, or it can be richer in germanium (e.g up to about 20% higher in Ge content, and may be pure Ge) for narrower bandgap to promote more effective tunneling behavior. The tunneling interface is between the p-type bottom tunnel junction portion and the n-type top tunnel junction portion.

Transition layers 109 can be provided between the tunnel junction layers 108 and the GaAsP subcell 110. The transition layers may include a bottom transition layer interfacing tunnel junction 108 and comprising for example pure germanium, having n type doping levels of about 1e¹⁸-1e²⁰ cm⁻³, or for example levels of about 5e¹⁸-5e¹⁹ cm⁻³, with a thickness of 5-30 nm. The transition layers may also include a top transition layer interfacing GaAsP subcell 110 comprised of a III-V semiconductor approximately lattice matched to the terminal portion of graded buffer 104, for example an InGaP layer with a thickness of about 10-100 nm and n-type doping of 1e¹⁸-1e¹⁹ cm⁻³ can be provided. The purpose of the top transition layer is to allow for the initiation of quality III-V semiconductor growth on top of the group IV semiconductor layers below. This and subsequently described III-V layers can be grown in an MOCVD (Metal Oxide Chemical Vapor Deposition) system such as a Veeco TurboDisc As/P (Arsenide/Phosphide) MOCVD System, by methods well known in the art.

The GaAsP subcell 110 can include a back surface field layer which may have a lattice constant approximately matching the terminal composition of graded buffer 104, and thickness of between e,g. 50-200 nm, with n type doping levels of about 1e¹⁷-1e¹⁹ cm⁻³, or for example between 3e¹⁷-3e¹⁸ cm⁻³. This layer may be comprised of GaAsP, or of a wider-bandgap semiconductor layer such as InGaP. GaAsP subcell 110 can include a GaAsP base layer above the back surface field layer, which may have lattice constant approximately matching the terminal composition of graded buffer 104, and a thickness of between 0.2-2.0 um, with n type doping levels of about 1e¹⁶-1e¹⁸ cm⁻³, or for example about 1e¹⁷-2e¹⁷ cm⁻³. Alternately, the GaAsP base layer can be slightly tensile, with for example about 0.05-0.15% strain. A GaAsP emitter layer may be grown above the GaAsP base layer with p type doping of e.g. 1e¹⁷-1e¹⁹ cm⁻³, or about 1e¹⁸-3e¹⁸ cm⁻³, and with a lattice constant similar to the GaAsP base layer. The GaAsP emitter layer can have a thickness of about 50-200 nm, or about 100 nm. Additional layers can include a window layer of AlInP or InGaP, for example with a lattice constant similar to the underlying GaAsP base and emitter layers, and thickness of between 10-50 nm, with p type doping levels of for example about 2e¹⁷-2e¹⁸ cm⁻³. Alternately, the window layers may be somewhat tensile, with up to e.g. 2% tensile strain, allowing a wider bandgap for less ultraviolet absorption. A GaAsP or GaAs contact layer can also be provided with a lattice constant similar to the terminal portion of graded buffer 104, and a thickness of between 100-500 nm with p type doping levels of about 5e¹⁸-1e²⁰ cm⁻³. The contact layer may be removed via wet etching after subsequent top contact grid formation, and thus only remain under the top contact grid in the final structure, an approach which is well known in the art of making III-V-based multi-junction solar cells. An exemplary process of creating a GaAsP cell is known in the art. For example, see Vernon et al., “Development of high-efficiency GaAsP solar cells on compositionally graded buffer layers”, page 108-112, IEEE Photovoltaic Specialists Conference, 19th, New Orleans, La., May 4-8, 1987, Proceedings.

Top contacts 112 can be provided on the exposed surface of the GaAsP subcell 110. The top contacts 112 can be provided by known methods in the art. For example, a grid structure of CrAu with a thickness of e.g. 1 um-5 um may be provided. Anti-reflection coating (ARC) of silicon nitride with a thickness of about 10-500 nm can also be provided to improve the solar cell efficiency. Methods and materials for providing top contacts and top ARC for III-V-based multi-junction solar cells is well known in the art.

The bottom contact surface of the substrate 102 can be textured with KOH (potassium hydroxide) or TMAH, as is known in the art, to provide a pyramidally textured surface. Such a surface will cause light redirection upon reflection from the rear surface. Re-direction of the light away from a direction substantially normal to the top solar cell surface promotes total internal reflection. A thin (e.g. 10-1000 nm, or for example about 100 nm) dielectric layer of e.g. SiNₓ or SiO₂ can be deposited on the bottom of substrate 102, after optional texturing takes place. This layer, not shown, can be between layers 102 and 114 in FIG. 2d. If this dielectric layer is provided, a grid or other pattern of regularly openings can be provided over a small percentage of the dielectric area (e.g. 0.5-10% of the total) to allow electrical contact between the subsequently deposited rear contact metal and the substrate 102. These openings can be formed by e.g. photolithography or laser ablation [see e.g. “Selective Laser Ablation of Dielectric Layers”, S. Correia et al., Proceedings of 22nd European Photovoltaic Solar Energy Conference, 3-7 Sep. 2007] or ink jet printing of dielectric etchants [see e.g. “Direct patterned etching of silicon dioxide and silicon nitride dielectric layers by ink jet printing”, A. Lennon et al., Solar Energy Materials & Solar Cells 93 (2009) p 1865-1874]. Such openings can be round and e.g. 1-100 microns in diameter. Bottom contact metal layer 114 can be provided by depositing metal, e.g. aluminum or silver with a thickness of about 0.5-2.0 microns, by PVD or by methods well known in the art. The deposition of top and bottom contacts can be followed by an annealing step at e.g. 300-500° C. to reduce resistance between the contacts and the semiconductor layers. In addition to providing rear electrical contact, this rear metal provides a reflective surface to promote internal reflection of any light which has passed through both the GaAsP top subcell and the bottom SiGe subcell, improving light collection in the solar cell. Because the silicon substrate has a much wider energy bandgap than the bottom SiGe subcell, any light that is unabsorbed after passing through the SiGe subcell will be well below the energy bandgap of silicon. Thus, the Si substrate will be nearly transparent for the wavelengths in question, allowing multiple light reflections between the top and bottom interior surfaces of the solar cell. The purpose of the optional dielectric layer provided between substrate 102 and bottom contact metal layer 114 is to enhance rear surface reflection.

### Exemplary Method of Construction

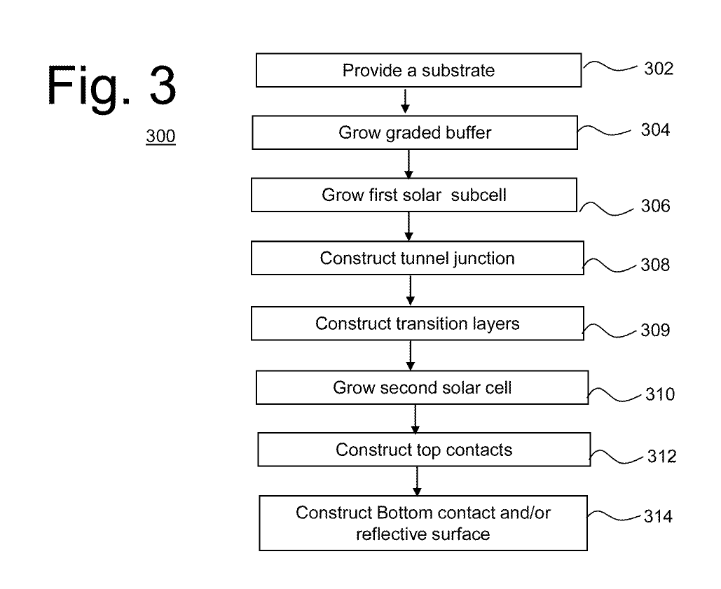

Referring to FIG. 3, an exemplary method of constructing a multi-junction solar cell device 300 may include the following actions. A silicon substrate 102, as previously described, is provided (block 302). Epitaxially grow a graded buffer layer 104 on top of the substrate 102 (block 304). Epitaxially grow a first solar subcell 106 on top of the graded buffer layer 104 (block 306). Epitaxially grow a tunnel junction 108 above the first solar subcell (block 308). Optionally grow transition layers 109 between tunnel junction 108 and a second solar subcell 110 (block 309). Epitaxially grow a second solar cell junction 110 on top of the tunnel junction transition layer 108 (block 310). Construct top contacts on a top surface of the second solar cell junction 110 (block 312). Construct bottom contact and/or reflective surface 114 on a bottom surface of the substrate 102 (block 314). The exemplary method of construction may be modified to incorporate other embodiments, for example, but not limited to actions associated with rear surface passivation and contacting as described in previous embodiments.

### Solar Cell on a Transparent Substrate

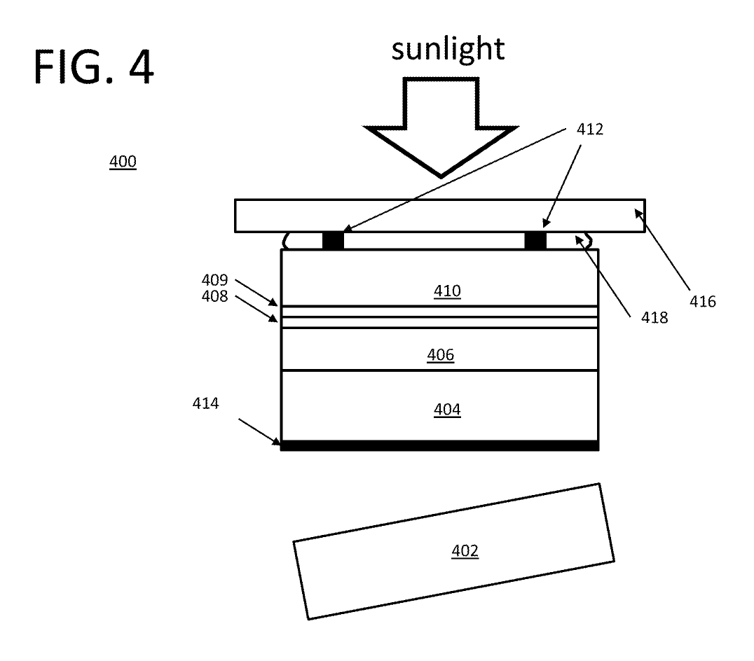

Referring to FIG. 4, the multi-junction cell on a transparent substrate 400 may have the exemplary basic structure. A monocrystalline silicon substrate 402 with a porous silicon layer 414 may be used to construct a base portion of a solar cell 400. A graded buffer layer 404 can be hetero-epitaxially grown on the porous silicon layer 414. A SiGe subcell 406 can be grown on the graded buffer layer 404. A GaAsP subcell 410 can be grown on the SiGe subcell 406. A tunnel junction 408 can be provided between the GaAsP subcell 410 and the SiGe subcell 406. Transition layers 409 can be provided between the tunnel junction 408 and GaAsP subcell 410. Top contacts 412 can be provided on the exposed surface of the GaAsP subcell 410. Bottom contact and/or reflective surface 414 can be provided on the bottom surface of the substrate after removal of the substrate 402. Although exemplary embodiments describe a SiGe subcell, embodiments are not limited to SiGe and can include a solar cell constructed of other materials suitable for providing a graded buffer. Additionally, embodiments are not limited to a top GaAsP subcell and can include a solar cell constructed of other material suitable for growth over the bottom subcell.

### Exemplary Solar Cell on a Transparent Substrate Production

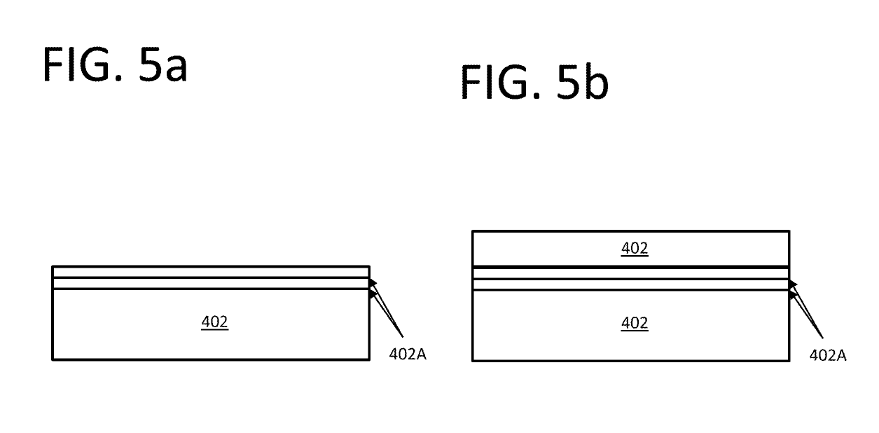

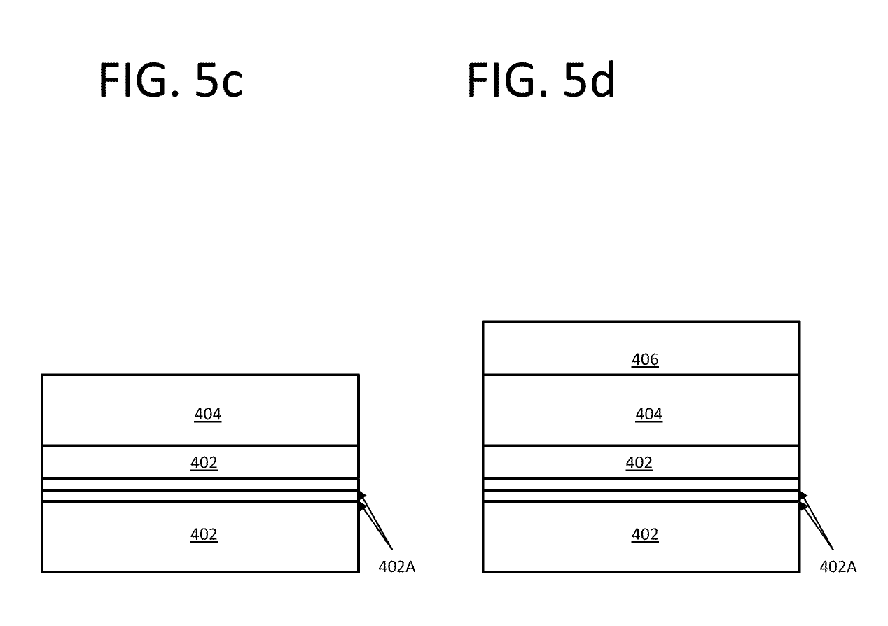

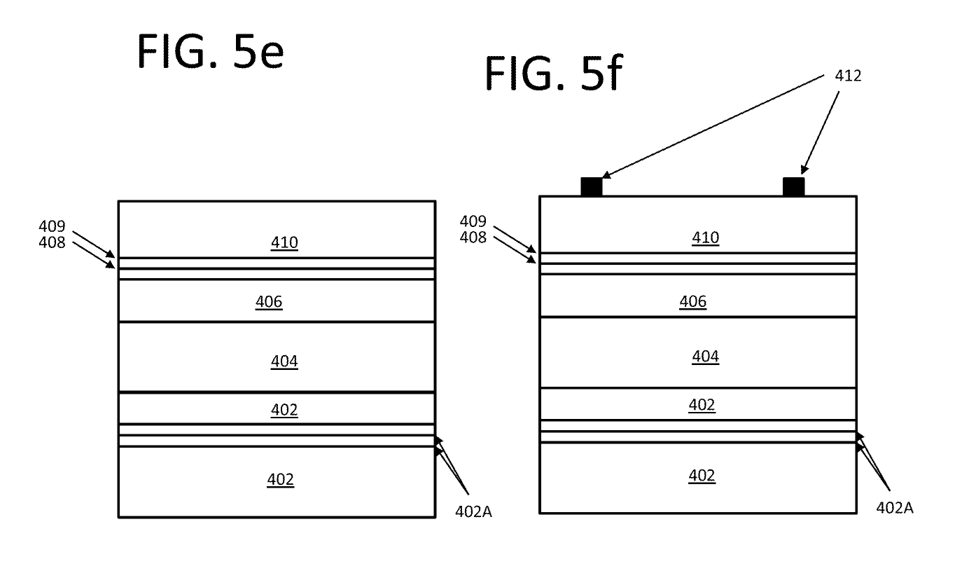

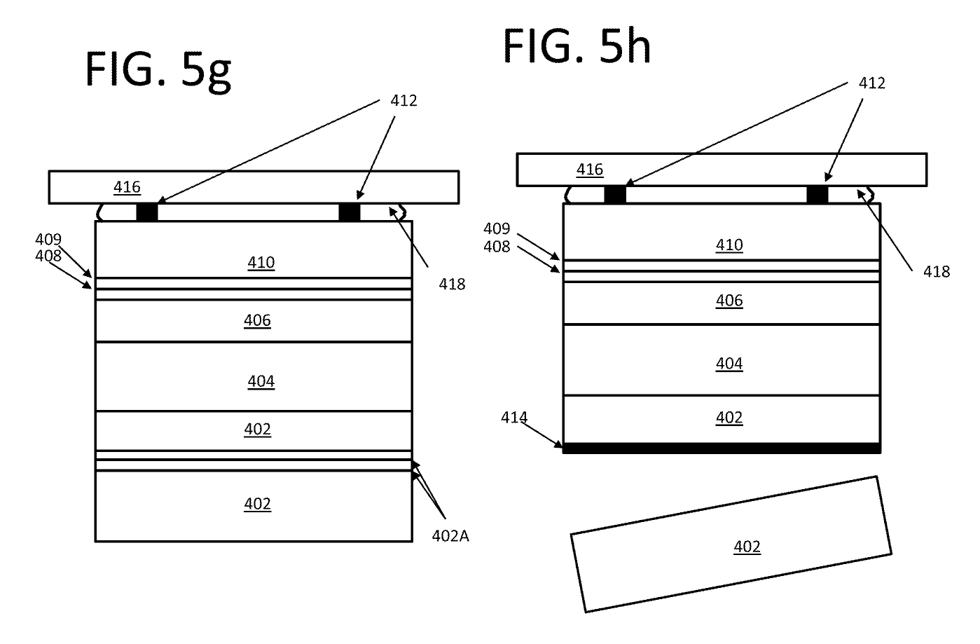

Referring to FIGS. 5(a-h), an exemplary solar cell device is constructed in accordance with an exemplary transparent substrate embodiment of the invention. The starting substrate 402 may be monocrystalline silicon with n-type doping, for example arsenic or phosphorous, for example in the range 1×10¹⁶ cm⁻³ to 1×10¹⁹ cm⁻³. Substrate 402 may be, for example, but not limited to, a (100) surface orientation with an offcut of 2-8 degree towards a <110> or <111> direction; for example, the surface offcut may be 4-6 degrees toward a <110> or <111> direction. The substrate 102 may have a thickness of about 100-1000 microns; for example; for example, the thickness may between 200 and 500 microns. The donor substrate 402 can be metallurgical grade monocrystalline silicon. The diameter of the donor substrate 402 may be, but is not limited to, standard wafer sizes of about 100-300 mm. Alternately, donor substrate 402 may be square or semi-square with a size of e.g. 125 mm or 156 mm across, typical sizes for Si solar cells.

A porous silicon layer 402a may be used to construct a base portion of a solar cell 400. The donor substrate 402 may be p-type and have resistivity below about 1 ohm-cm. Dual porous layers 402a may be formed on the surface of the donor substrate 402. The top porous layer may have a lower porosity, to serve as a template for subsequent epitaxial growth. The bottom porous layer may have a higher porosity, to allow subsequent splitting. An exemplary approach to creating a splitting plane is known in the art and is described in, for example, Yonehara & Sakaguchi, JSAP Int. July 2001, No. 4, pp. 10-16. The porous layers 402a may also be stabilized via brief thermal oxidation and may also be sealed via anneal under H2 as described in Yonehara & Sakaguchi.

Details of an exemplary process for forming porous Si splitting layers are as follow. A p-type (100)-oriented monocrystalline Si donor substrate 402, with resistivity between 0.01-0.02 ohm-cm, may be immersed in a solution composed of one part hydrofluoric acid, one part water, and one part iso-propyl alcohol. The substrate holder is electrically insulating, forcing electrical current to pass through the substrate and not around the wafer periphery. The donor substrate 402 is in series and in-line with two silicon electrodes, one facing the front of the wafer and the other facing the back. The electrodes are equal to or greater than the diameter of the substrate and are separated from the substrate by a distance of at least 10% of the diameter of the substrate. Two different voltages are applied between the electrodes, resulting in the formation of two different porous silicon layers 402a at different current densities. The first layer, which may be etched at a current density of 2-10 mA/cm2 to a depth of 0.5-2 microns (etch time approximately 0.5-5 minutes), is low porosity (approximately 25%). The second layer, buried under the first layer and which may be etched at a current density of 40-200 mA/cm2 to a depth of 0.25-2 microns (etch time approximately 2-30 seconds), is higher porosity. The second layer defines a cleave plane after subsequent cleaning, epitaxy, and bonding, described in further detail below. After etching, the wafers may be immersed in a mixture of sulfuric acid and hydrogen peroxide, self-heating to approximately 80-140° C., for 10 minutes. Other standard semiconductor cleaning solutions, such as SC-1, SC-2, hydrofluoric acid, hydrochloric acid, or iso-propyl alcohol, may also be used. Wafers may then be loaded into the silicon growth system.

The graded buffer layer 404 can be hetero-epitaxially grown on the porous silicon layer 402a as is described in greater detail later herein. A CVD reactor such as an ASM Epsilon 2000 can be used to produce the relaxed grade buffer layer on porous layer 402a; the various doping levels described in the graded buffer structure and SiGe subcell layers can be incorporated in-situ during epitaxial growth, by means well known in the art. The composition of the graded buffer layer 404 can be initiated with a 0% or relatively low germanium composition. A germanium content, x, of the Si₁₋ₓGeₓ layer is controlled by the relative concentration of the silicon and germanium precursors. By increasing the germanium content gradually, the strain due to lattice mismatch between silicon and germanium is gradually relieved, thereby minimizing threading dislocation density in the deposited relaxed SiGe layer. Typically, the germanium content of the graded Si₁₋ₓGeₓ layer is increased at a rate of about 10%-25% Ge per micron; however, embodiments need not be limited to that range. A final graded Si₁₋ₓGeₓ layer can comprise a 50-90% germanium composition or for example 70-85% germanium composition. However, embodiments are not limited to that composition and various grading layers may be incorporated or may form a portion of the SiGe subcell 406. Alternately, a batch epitaxy reactor can be used in place of the CVD reactor.

The SiGe subcell 406 can include a back surface field layer interfacing graded buffer layer 404, with Ge composition anywhere between 50-90%, approximately matched to the terminal germanium composition of graded buffer layer 404. The back surface field layer can have a thickness of e.g. 50-500 nm with p type doping levels of about 1e17-1e19 cm−3, or for example 3e17-3e18 cm−3. In an alternative embodiment, the back surface field layer may be tensile, with a germanium content lower than that of the terminal composition of graded buffer layer 404, for example about 25% lower Ge; in this case, the thickness of the back surface field layer may be thinner, for example about 20-100 nm. Due to the energy band offsets introduced by tension, a tensile back surface field layer may be more effective than a lattice-matched one. SiGe subcell 406 can include a base layer, with a Ge composition anywhere between 50-90%, approximately matched to the terminal germanium composition of graded buffer layer 404. The base layer can have a thickness of between 0.5-5.0 um with p type doping levels of about 1e15-1e17 cm−3. If the back surface field layer is included it can be below and in contact with the base layer.

An emitter layer can be grown on top of the base layer having a similar germanium composition or matched to the surface of the base layer. The emitter layer can have a n type doping level of 5e¹⁷-5e¹⁹ cm⁻³, or for example levels of about 1e18-5e18 cm−3.

The emitter layer can have a thickness of about 100-2000 nm, or for example about 200-500 nm. An optional transition layer (not shown) can be provided between the SiGe subcell 406 and the GaAsP subcell 410. The transition layer can be, for example, a 100% germanium layer having n type doping levels of about 1e18-1e20 cm−3, or for example levels of about 5e18-5e19 cm−3 with a thickness of 5-15 nm. On top of this transition layer, a III-V nucleation layer of InGaP (not shown) with a thickness of about 10-100 nm and doping of 1e18-1e19 cm−3 can be provided. The doping type (n or p) of the III-V nucleation layer may match that of the layer immediately beneath and in contact with the III-V nucleation layer, to avoid forming a junction. The purpose of the nucleation layer is to allow for the initiation of quality III-V semiconductor growth on top of the group IV semiconductor layers (SiGe) below. This and subsequently described III-V layers can be grown in an MOCVD (Metal Oxide Chemical Vapor Deposition) system such as a Veeco TurboDisc As/P (Arsenide/Phosphide) MOCVD System, by methods well known in the art.

The tunnel junction 408 can be provided between the SiGe subcell 406 and GaAsP subcell 410. The tunnel junction 408 can comprise a bottom tunnel junction portion comprised of SiGe interfacing SiGe subcell 406, with n-type doping levels of about 7e¹⁸-1e²⁰ cm⁻³ with a thickness of 5-20 nm. The percent of germanium can be approximately matched to the terminal germanium composition of graded buffer 404, or it can be richer in germanium (e.g up to about 20% higher in Ge content, and may be pure Ge) for narrower bandgap to promote more effective tunneling behavior. A top SiGe tunnel junction portion can be provided having p type doping levels of about 7e¹⁸-1e²⁰ cm⁻³ with a thickness of 5-20 nm. Again, the percent of germanium can be approximately matched to the terminal germanium composition of graded buffer 404, or it can be richer in germanium (e.g up to about 20% higher in Ge content, and may be pure Ge) for narrower bandgap to promote more effective tunneling behavior. The tunneling interface is between the n-type bottom tunnel junction portion and the p-type top tunnel junction portion.

Transition layers 409 can be provided between the tunnel junction layers 408 and the GaAsP subcell 410. The transition layers may include a bottom transition layer interfacing tunnel junction 408 and comprising for example pure germanium, having p type doping levels of about 1e¹⁸-1e²⁰ cm⁻³, or for example levels of about 5e¹⁸-5e¹⁹ cm⁻³, with a thickness of 5-30 nm. The transition layers may also include a top transition layer interfacing GaAsP subcell 410 comprised of a III-V semiconductor approximately lattice matched to the terminal portion of graded buffer 404, for example an InGaP layer with a thickness of about 10-100 nm and p-type doping of 1e¹⁸-1e¹⁹ cm⁻³ can be provided. The purpose of the top transition layer is to allow for the initiation of quality III-V semiconductor growth on top of the group IV semiconductor layers below. This and subsequently described III-V layers can be grown in an MOCVD (Metal Oxide Chemical Vapor Deposition) system such as a Veeco TurboDisc As/P (Arsenide/Phosphide) MOCVD System, by methods well known in the art.

The GaAsP subcell 410 can include a back surface field layer which may have a lattice constant approximately matching the terminal composition of graded buffer 404, and thickness of between e,g. 50-200 nm, with p type doping levels of about 1e¹⁷-1e¹⁹ cm⁻³, or for example between 3e¹⁷-3e¹⁸ cm⁻³. This layer may be comprised of GaAsP, or of a wider-bandgap semiconductor layer such as InGaP. GaAsP subcell 410 can include a GaAsP base layer above the back surface field layer, which may have lattice constant approximately matching the terminal composition of graded buffer 404, and a thickness of between 0.2-2.0 um, with p type doping levels of about 1e¹⁶-1e¹⁸ cm⁻³, or for example about 1e¹⁷-2e¹⁷ cm⁻³. Alternately, the GaAsP base layer can be slightly tensile, with for example about 0.05-0.15% strain. A GaAsP emitter layer may be grown above the GaAsP base layer with n type doping of e.g. 1e¹⁷-1e¹⁹ cm⁻³, or about 1e¹⁸-3e¹⁸ cm⁻³, and with a lattice constant similar to the GaAsP base layer. The GaAsP emitter layer can have a thickness of about 50-200 nm, or about 100 nm. Additional layers can include a window layer of AlInP or InGaP, for example with a lattice constant similar to the underlying GaAsP base and emitter layers, and thickness of between 10-50 nm, with n type doping levels of for example about 2e¹⁷-2e¹⁸ cm⁻³. Alternately, the window layers may be somewhat tensile, with up to e.g. 2% tensile strain, allowing a wider bandgap for less ultraviolet absorption. A GaAsP or GaAs contact layer can also be provided with a lattice constant similar to the terminal portion of graded buffer 404, and a thickness of between 100-500 nm with n type doping levels of about 5e¹⁸-1e²⁰ cm⁻³. The contact layer may be removed via wet etching after subsequent top contact grid formation, and thus only remain under the top contact grid in the final structure, an approach which is well known in the art of making III-V-based multi-junction solar cells. An exemplary process of creating a GaAsP cell is known in the art. For example, see Vernon et al., “Development of high-efficiency GaAsP solar cells on compositionally graded buffer layers”, page 108-112, IEEE Photovoltaic Specialists Conference, 19th, New Orleans, La., May 4-8, 1987, Proceedings.

Top contacts 412 can be provided on the exposed surface of the GaAsP subcell 410. The top contacts 412 can be provided by known methods in the art. For example, a grid structure of AuGe with a thickness of e.g. 1 um-5 um may be provided. It should be noted that a CrAu grid structure can be used for a P-type surface. Anti-reflection coating (ARC) of silicon nitride with a thickness of about 10-500 nm can also be provided to improve the solar cell efficiency. Methods and materials for providing top contacts and top ARC for III-V based multi-junction solar cells are well known in the art. A transparent substrate 416 can be bonded to the top surface of the multi-junction solar cell to provide support and protection. The transparent substrate 416 can be, for example, a sheet of module glass. The transparent substrate 416 can be bonded to the top surface by epoxy 418 or other methods of bonding.

The donor substrate 402 may be removed from the first portion of a solar cell bonded to the transparent substrate 416 by cleaving the donor substrate 402 within the porous layers 402a. Separation may be via mechanical force alone, or enhanced with various other methods. For example, a wedged device (not shown) may be applied to induce separation at the exposed external edges of the porous region 402a. In another example, separation may be enhanced via application of a high pressure water jet directed at the edge of the porous silicon layers 402a, as described in Yonehara & Sakaguchi. In yet another example, a wet acid solution, such as HF/H202, may also be exposed to the porous region 402a to erode the porous region 402a from the edge and enhance separation. It should be understood that the above examples of separation may be used individually or in various combinations.

The bottom contact surface of the substrate 402 can be textured with NaOH, KOH (potassium hydroxide) or TMAH, or by other means such as plasma etching, or sand blasting as is known in the art, to provide a pyramidally textured surface. Such a surface will cause light redirection upon reflection from the rear surface. Re-direction of the light away from a direction substantially normal to the top solar cell surface promotes total internal reflection. A thin (e.g. 10-1000 nm, or for example about 100 nm) dielectric layer of e.g. SiNₓ or SiO₂ can be deposited on the bottom of substrate 402, after optional texturing takes place. This layer, not shown, can be between layers 402 and 414 in FIG. 5h. If this dielectric layer is provided, a grid or other pattern of regularly openings can be provided over a small percentage of the dielectric area (e.g. 0.5-10% of the total) to allow electrical contact between the subsequently deposited rear contact metal and the substrate 402. These openings can be formed by e.g. photolithography or laser ablation, [see e.g. “Selective Laser Ablation of Dielectric Layers”, S. Correia et al., Proceedings of 22nd European Photovoltaic Solar Energy Conference, 3-7 Sep. 2007] or ink jet printing of dielectric etchants [see e.g. “Direct patterned etching of silicon dioxide and silicon nitride dielectric layers by ink jet printing”, A. Lennon et al., Solar Energy Materials & Solar Cells 93 (2009) p 1865-1874]. Such openings can be round and e.g. 1-100 microns in diameter. Bottom contact metal layer 414 can be provided by depositing metal, e.g. aluminum or silver with a thickness of about 0.5-2.0 microns, by PVD or by methods well known in the art. The deposition of top and bottom contacts can be followed by an annealing step at, for example, 300-500 C to reduce resistance between the contacts and the semiconductor layers. In addition to providing rear electrical contact, this rear metal provides a reflective surface to promote internal reflection of any light which has passed through both the GaAsP top subcell and the bottom SiGe subcell, improving light collection in the solar cell. Because the silicon substrate has a much wider energy bandgap than the bottom SiGe subcell, any light that is unabsorbed after passing through the SiGe subcell will be well below the energy bandgap of silicon. Thus, the Si substrate will be nearly transparent for the wavelengths in question, allowing multiple light reflections between the top and bottom interior surfaces of the solar cell. The purpose of the optional dielectric layer provided between substrate 402 and bottom contact metal layer 414 is to enhance rear surface reflection.

### Exemplary Method of Construction

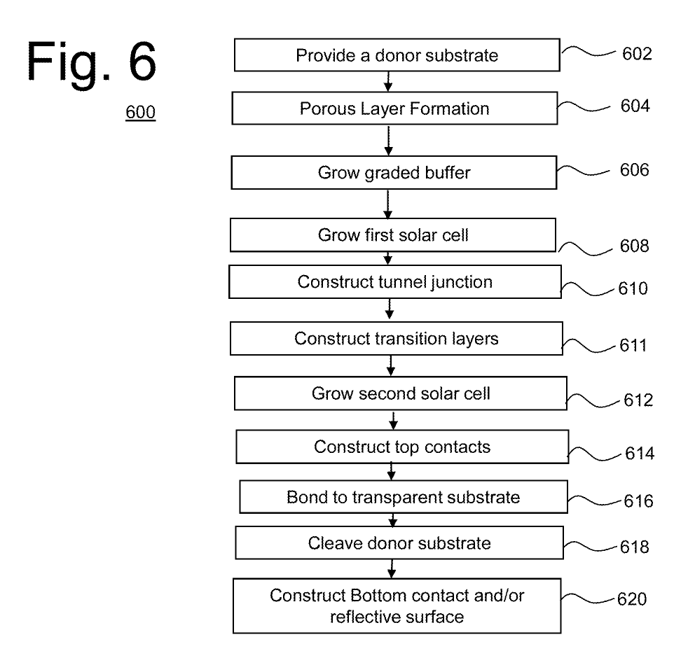

Referring to FIG. 6, an exemplary method of constructing a multi-junction solar cell device 600 may include the following actions. A silicon donor substrate 402, as previously described, is provided (block 602). A porous region 402a is formed on the donor substrate 402 (block 604). Epitaxially grow a graded buffer layer 404 on top of the porous region 402a or the portion of the substrate above the porous region 102 (block 606). Epitaxially grow a first solar subcell junction 406 on top of the graded buffer layer 404 (block 608). Epitaxially grow a tunnel junction 408 above the first solar subcell (block 610). Optionally grow transition layers 409 between the tunnel junction 408 and a second solar subcell junction 410 (block 611). Epitaxially grow a second solar subcell junction 410 on top of the tunnel junction transition layer 408 (block 612). Construct top contacts on a top surface of the second solar subcell junction 410 (block 614). Bond a transparent substrate 416 onto the top surface of the second solar subcell junction 410 (block 616). Cleave the donor substrate 402 from the multi-junction solar cell 400 at the porous region 402a (block 618). Construct bottom contact and/or reflective surface 414 on a bottom surface of the multi-junction solar cell 400 (block 620). The exemplary method of construction may be modified to incorporate other embodiments, for example, but not limited to actions associated with rear surface passivation and contacting as described in previous embodiments.

### Alternative Embodiment #1

In an alternative embodiment, the solar cell can be grown on a p-type silicon substrate instead of n-type. In this case, the doping type of each layer of graded buffer 104, SiGe subcell 106, tunnel junction 108, transition layers 109, and GaAsP subcell 110 will be reversed, n-type instead of p-type and vice versa. In this embodiment, to increase current in the SiGe subcell 106, a SiGe superlattice may be employed. In this case the SiGe base region may include thin layers of high and low Ge content. For example, the SiGe base region may include e.g. 10 compressively strained layers of SiGe e.g. 30 nm thick, with Ge content e.g. 10% higher than the terminal germanium composition of graded buffer layer 104. These layers could be interleaved with e.g. 10 tensiley strained layers of SiGe e.g. 30 nm thick, with Ge content e.g. 10% lower than the terminal germanium composition of graded buffer layer 10. Such a superlattice of alternating compressive and tensile layers is said to be ‘strained balanced’, and can include an arbitrary number of alternating strained layers without relaxing. A benefit of this approach is that the high-Ge-content layers capture low energy photons that would otherwise pass through the solar cell. The energy band alignments of compressively versus tensily strained SiGe layers are such that the conduction band offsets between such alternating regions are minimal, allowing relatively free flow of photogenerated minority carrier holes.

### Alternative Embodiment #2

In another alternative embodiment, for the case of an n-type substrate, n-type base regions and p-type emitter regions as originally described above, the bottom transition layer of e.g. pure Ge can be omitted from transition layers 109, and the top transition layer (a III-V semiconductor) interfaces directly with tunnel junction 108. In this case, the well known autodoping effect may be used to produce or to increase the n-type doping in top portion of tunnel junction 108. The autodoping effect is where, where under proper growth conditions, the growth of a III-V semiconductor containing P or As causes n-type doping of an immediately underlying group IV semiconductor surface, through diffusion of P or As into the group IV semiconductor. The conditions employed to create the autodoping effect is well known in the art, yet as an example, the P or As diffusion is commonly employed during the heat-up and bake of the substrate while having an overpressure of the Group V source. The depth and amount of P or As diffusion is controlled by the temperature and time of baking before the initiation of the Group III source, which initiates the growth of the III-V semiconductor. It is because our solar cell design optionally allows the n-type portion of tunnel junction 108 to directly interface a III-V semiconductor layer (the above-described top transition layer, for the case where the bottom transition layer is omitted) that we can take advantage of the autodoping effect to increase or even to create the n-type doping in the top portion of tunnel junction 108.

### Alternative Embodiment #3

In an alternative embodiment, for the case of an n-type substrate, n-type base regions and p-type emitter regions as originally described above, the bottom transition layer of e.g. pure Ge can be omitted from transition layers 109, and additionally the n-type SiGe portion of tunnel junction 108 may be omitted. In this case, the tunneling interface is directly between a p-type SiGe tunnel junction region and an n-type III-V transition layer such as InGaP.

### Alternative Embodiment #4

In an alternative embodiment, a porous Si Bragg reflector can be included below the SiGe subcell, to improve reflectance of light that has passed through the SiGe subcell. The means to produce a porous Si Bragg reflector, and to subsequently grow quality epitaxy on top, are described for example in Niewenhuysen et al. “Epitaxial thin film silicon solar cells with CVD grown emitters exceeding 16% efficiency”, 34th IEEE PVSC, (2009). This reflector can be either instead of, or in addition to, a reflector on the rear surface of the silicon handle wafer as described above.

### Alternative Embodiment #5

In an alternative embodiment, a supplemental top contact layer may be provided to allow more flexibility in top contact metallurgy. While III-V layers are typically contacted with stacks of multiple metals often including expensive Au, silicon can be contacted by single low-cost metals such as Aluminum. Therefore, one may deposit on top of GaAsP subcell 110, via e.g. PECVD, a thin in-situ doped amorphous or microcrystalline Si layer, with doping type the same as the top of GaAsP subcell 110. The means of depositing such via PECVD are well known in the art. This layer may be deposited directly on top of and in contact with a III-V contact layer such as GaAs or GaAsP on top of GaAsP subcell 110. Alternately, the III-V contact layer may be omitted, and the amorphous Si may be deposited directly on top of the window layer of GaAsP subcell 110.

Other modifications and substitutions by one of ordinary skill in the art are considered to be within the scope of the present invention, which is not to be limited except by the following claims.

The invention claimed is:

1. A multi-solar cell structure comprising:
a substrate;
a graded buffer layer grown on the substrate;
a first solar subcell within or on top of the graded buffer layer; and
a second solar subcell grown on top of the first solar subcell.

2. A multi-solar cell structure of claim 1, wherein the substrate is silicon, the graded buffer layer composition is graded silicon germanium, and the second solar subcell is comprised of GaAsP or other III-V material.

3. A multi-solar cell structure of claim 1, further comprising top contacts on top of the second solar subcell.

4. A multi-solar cell structure of claim 1, wherein the substrate is a monocrystalline silicon substrate with n-type doping material.

5. A multi-solar cell structure of claim 1, wherein the substrate is metallurgical grade monocrystalline silicon.

6. A multi-solar cell structure of claim 1, wherein the graded buffer layer is SiGe with a grading rate of about 10%-25% germanium per micron.

7. A multi-solar cell structure of claim 1, wherein the graded buffer layer has a final graded SiGe layer of 70-85% germanium composition.

8. A multi-solar cell structure of claim 1, further comprising a back surface field layer interfacing with the graded buffer layer and approximately matched to a final germanium composition of the graded buffer layer.

9. A multi-solar cell structure of claim 1, further comprising a tunnel junction between the first solar subcell and the second solar subcell.

10. A multi-solar cell structure of claim 9, further comprising a transition layer between the tunnel junction and the second solar subcell.

11. A method of making a multi-junction solar cell comprising the actions of:
providing a silicon substrate;
growing a silicon germanium graded buffer layer on the substrate;
growing a first solar subcell base layer and a first solar subcell emitter layer within or on top of the graded buffer layer; and
growing a second solar subcell base layer and a second solar subcell emitter layer of GaAsP or other III-V material on top of the first solar subcell absorber layer and the first solar subcell emitter layer.

12. A method of making a multi-junction solar cell of claim 11, further comprising the action of:
constructing top contacts on top of the second solar subcell base layer and the second solar subcell emitter layer and
constructing a transparent substrate on top of the top contacts.

13. A method of making a multi-junction solar cell of claim 11, further comprising the action of:
removing a portion of the silicon substrate.

14. A method of making a multi-junction solar cell of claim 11, wherein the substrate is metallurgical grade monocrystalline silicon.

15. A method of making a multi-junction solar cell of claim 11, wherein the graded buffer layer is SiGe with a grading rate of about 10%-25% germanium per micron.

16. A method of making a multi-junction solar cell of claim 11, wherein the graded buffer layer has a final graded SiGe layer of 70-85% germanium composition.

17. A method of making a multi-junction solar cell of claim 11, further comprising the action of:
constructing a back surface field layer interfacing the graded buffer layer and approximately matched to a final germanium composition of the graded buffer layer.

18. A method of making a multi-junction solar cell of claim 11, further comprising the action of:
constructing a tunnel junction between the first solar subcell and the second solar subcell.

19. A method of making a multi-junction solar cell of claim 18, further comprising the action of:
constructing a transition layer between the tunnel junction and the second solar subcell.

20. A multi-solar cell structure comprising:
a monocrystalline silicon substrate with n-type doping;
a silicon germanium graded buffer layer grown on the substrate with a grading rate of about 10%-25% germanium per micron and a final grade of 70-85% germanium composition;
a first solar subcell of SiGe on the graded buffer layer;
a second solar subcell of GaAsP or other III-V material grown on top of the first solar subcell; and
a tunnel junction between the first solar subcell and the second solar subcell and a transition layer between the tunnel junction and the second solar subcell.
